(19) United States
(12) Patent Application Publication
(10) Pub. No.: US 2025/0311551 A1
(43) Pub. Date: Oct. 2, 2025

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Haijun YU, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 18/705,480

(22) PCT Filed: Apr. 9, 2024
(86) PCT No.: PCT/CN2024/086705

§ 371 Date: Apr. 26, 2024

(30) Foreign Application Priority Data
Mar. 29, 2024 (CN) 202410381143.5

(51) Int. Cl. H10K 59/122; H10K 50/19

(52) U.S. Cl. CPC H10K 59/122; H10K 50/19

(57) ABSTRACT

A display panel and a display device are provided. An isolation structure includes a first isolation layer and a second isolation layer. In the second isolation layer, a minimum opening area of a second sub-opening is larger than a minimum opening area of a first sub-opening in the first isolation layer. Both the first light-emitting layer and the charge generation layer are interrupted at the isolation structure; the second electrode layer is continuously arranged at the isolation structure. An opening area of the first sub-opening on a side away from the substrate is greater than an opening area on a side close to the substrate.

### FIELD OF DISCLOSURE

The present application relates to a field of display technology, particularly to a display panel and a display device.

### DESCRIPTION OF RELATED ART

Organic light-emitting diode (OLED) devices are characterized by low power consumption, fast response time, and wide viewing angles, and hold broad application prospects. Currently, OLED display technology has been widely applied in various electronic products, ranging from small devices like smart bands, smart watches, smartphones, and tablets, to larger items like laptops, desktop computers, and televisions. To further enhance the efficiency and lifespan of OLED devices, tandem luminescence technology with stacked layers (Tandem display technology) has emerged. Tandem devices offer the advantages of higher brightness, longer lifespan, and lower power consumption, and there is a strong market demand for them at present.

Currently, it is common to add a charge generation layer in tandem OLED devices to improve device performance. However, the charge generation layer has a strong ability to generate and separate electrons, which can easily lead to unwanted light emission from adjacent pixels. This is generally prevented by isolating the charge generation layer to avoid the issue of unwanted light emission from adjacent pixels. However, isolating the charge generation layer can easily cause a short circuit between the charge generation layer and a cathode at the isolation points.

### SUMMARY OF INVENTION

The present application provides a display panel and a display device that can reduce the likelihood of unwanted light emission from adjacent pixels in the display panel, as well as reduce the probability of short circuits occurring between a charge generation layer and a second electrode layer.

Embodiments of the present application provide a display panel, including:
a substrate;
a first electrode layer, disposed on one side of the substrate, and including a plurality of first electrodes that are spaced apart;
a pixel definition layer, disposed on one side of the first electrode layer away from the substrate, wherein the pixel definition layer includes a plurality of pixel openings corresponding to the first electrodes and a first opening located between adjacent pixel openings;
an isolation structure, disposed between the substrate and the pixel definition layer, and arranged corresponding to the first opening, wherein isolation structure includes a first isolation layer and a second isolation layer stacked on each other, the second isolation layer is located between the substrate and the first isolation layer, the first isolation layer includes a first sub-opening corresponding to the first opening, the second isolation layer includes a second sub-opening corresponding to the first sub-opening, a minimum opening area of the second sub-opening is greater than a minimum opening area of the first sub-opening, and the second sub-opening communicates with the first opening through the first sub-opening;
a first light-emitting layer, disposed on one side of the pixel definition layer away from the substrate and interrupted at the isolation structure;
a charge generation layer, disposed on one side of the first light-emitting layer away from the pixel definition layer, and interrupted at the isolation structure;
a second light-emitting layer, disposed on one side of the charge generation layer away from the first light-emitting layer; and
a second electrode layer, disposed on one side of the second light-emitting layer away from the substrate, and continuously arranged at the isolation structure,
wherein an opening area of the first sub-opening on one side away from the substrate is greater than an opening area on one side near the substrate.

To achieve the above objectives of the present application, the present application further provides a display device, including a display panel, wherein the display panel includes:
a substrate;
a first electrode layer, disposed on one side of the substrate, and comprising a plurality of first electrodes that are spaced apart;
a pixel definition layer, disposed on one side of the first electrode layer away from the substrate, wherein the pixel definition layer comprises a plurality of pixel openings corresponding to the first electrodes and a first opening located between adjacent pixel openings;
an isolation structure, disposed between the substrate and the pixel definition layer, and arranged corresponding to the first opening, wherein isolation structure comprises a first isolation layer and a second isolation layer stacked on each other, the second isolation layer is located between the substrate and the first isolation layer, the first isolation layer comprises a first sub-opening corresponding to the first opening, the second isolation layer comprises a second sub-opening corresponding to the first sub-opening, a minimum opening area of the second sub-opening is greater than a minimum opening area of the first sub-opening, and the second sub-opening communicates with the first opening through the first sub-opening;
a first light-emitting layer, disposed on one side of the pixel definition layer away from the substrate and interrupted at the isolation structure;
a charge generation layer, disposed on one side of the first light-emitting layer away from the pixel definition layer, and interrupted at the isolation structure;
a second light-emitting layer, disposed on one side of the charge generation layer away from the first light-emitting layer; and
a second electrode layer, disposed on one side of the second light-emitting layer away from the substrate, and continuously arranged at the isolation structure,
wherein an opening area of the first sub-opening on one side away from the substrate is greater than an opening area on one side near the substrate.

### BRIEF DESCRIPTION OF DRAWINGS

The technical solutions and other beneficial effects of this application will become apparent through a detailed description of specific embodiments, in conjunction with the accompanying drawings.

FIG. 1 is a schematic structural view of a display panel in related conventional technology.

FIG. 2 is an equivalent circuit diagram of a luminescent device in the related conventional technology.

FIG. 3 is another equivalent circuit diagram of the luminescent device in the related conventional technology.

FIG. 4 is a schematic structural view of a display panel according to one embodiment of the present application.

FIG. 5 is an enlarged structural schematic view illustrating section Ain FIG. 4, according to one embodiment of the present application.

FIG. 6 is a schematic diagram illustrating parameters of an isolation structure in the display panel according to one embodiment of the present application.

FIG. 7 is a schematic structural view of a first luminescent layer and a second luminescent layer in the display panel according to one embodiment of the present application.

FIG. 8 is another enlarged structural schematic view of section A in FIG. 4, according to one embodiment of the present application.

FIG. 9 is yet another enlarged structural schematic view of section Ain FIG. 4, according to one embodiment of the present application.

### DETAILED DESCRIPTION OF EMBODIMENTS

The technical solutions in the embodiments of the present application are clearly and completely described below with reference to the accompanying drawings and in conjunction with specific embodiments. It is evident that the embodiments described herein are just a part of the embodiments of this application and do not represent all embodiments. Based on the embodiments in this application, all other embodiments obtained by those skilled in the art without any creative efforts are within the scope of protection of this application.

The following disclosure provides numerous different embodiments or examples for implementing various structures of this application. To simplify the disclosure, the following text describes specific components and configurations of particular examples. Certainly, these are provided merely as examples and are not intended to limit the scope of this application. Additionally, the application may repeat reference numbers and/or letters across different examples for the sake of simplicity and clarity; this repetition does not indicate any relationship between the various embodiments and/or configurations discussed. Furthermore, the application provides examples of specific techniques and materials, but those skilled in the art can recognize the applicability of other techniques and/or the use of other materials.

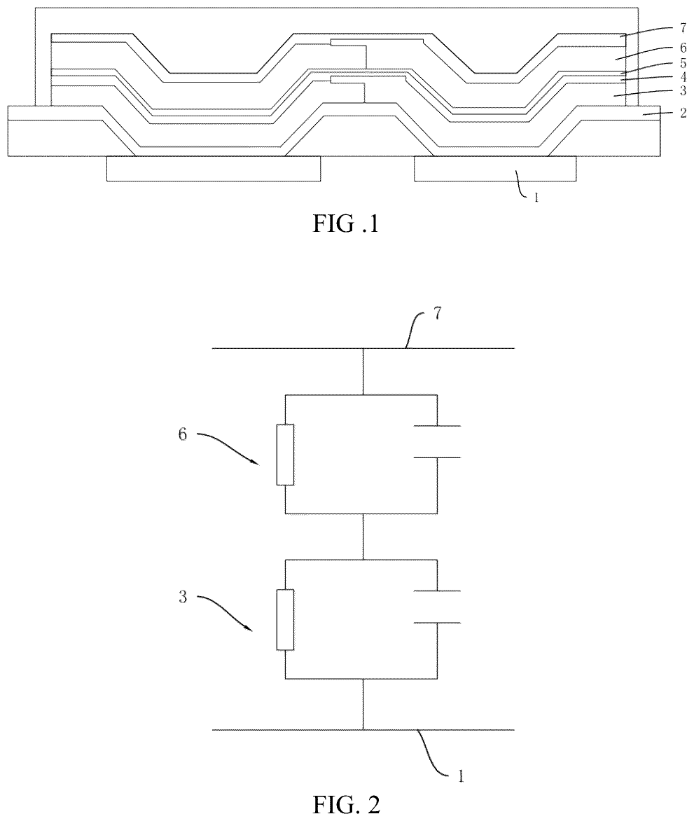

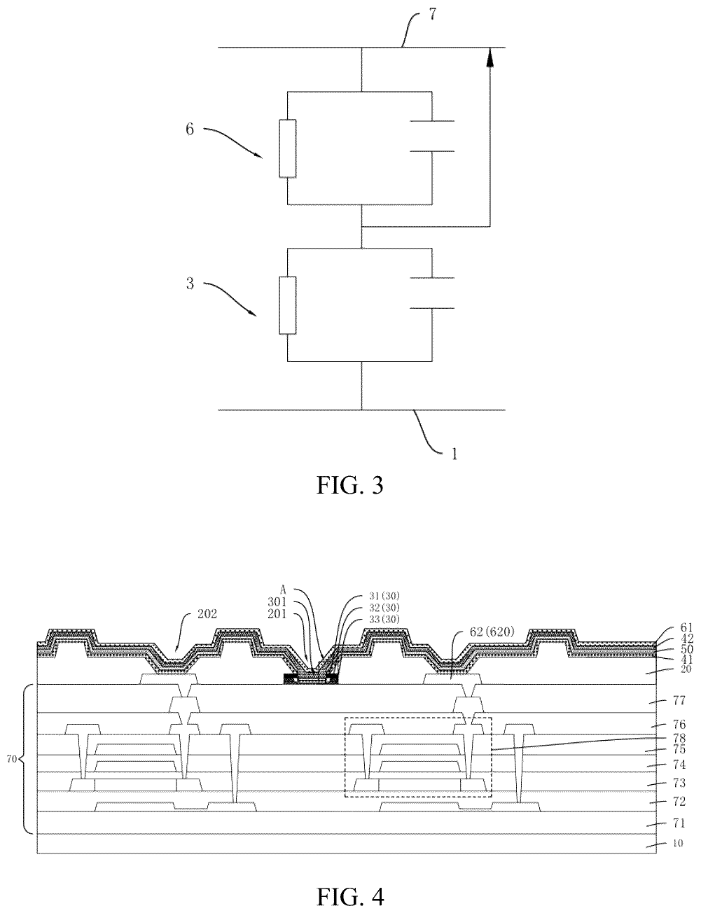

In the related conventional technology as depicted in FIGS. 1, 2, and 3, the display panel provided includes an OLED light-emitting device. The OLED device consists of an anode 1, a hole transport layer 2 arranged on the anode 1, a first light-emitting layer 3 located on the hole transport layer 2, an n-type charge generation layer 4 disposed on the first light-emitting layer 3, a p-type charge generation layer 5 disposed on the n-type charge generation layer 4, a second light-emitting layer 6 on the p-type charge generation layer 5, and a cathode layer 7 arranged on the second light-emitting layer 6. Due to the strong electron generation and separation capabilities of the n-type charge generation layer 4, it is prone to unintentionally lighting adjacent pixels. Therefore, a bottom-cut structure is commonly used in the related conventional technology to isolate the n-type charge generation layer 4 between adjacent pixels, reducing the likelihood of unintended activation of adjacent pixels. For example, a suspended part of the bottom-cut structure may be fabricated with an inverted trapezoidal side structure, which is more conducive to isolating the first light-emitting layer 3 and the n-type charge generation layer 4. However, this isolation process can also easily cause a short circuit between the n-type charge generation layer 4 and the cathode layer 7, thereby preventing the second light-emitting layer 6 from achieving its intended light-emitting effect, reducing the light efficiency and affecting the display performance of the display panel.

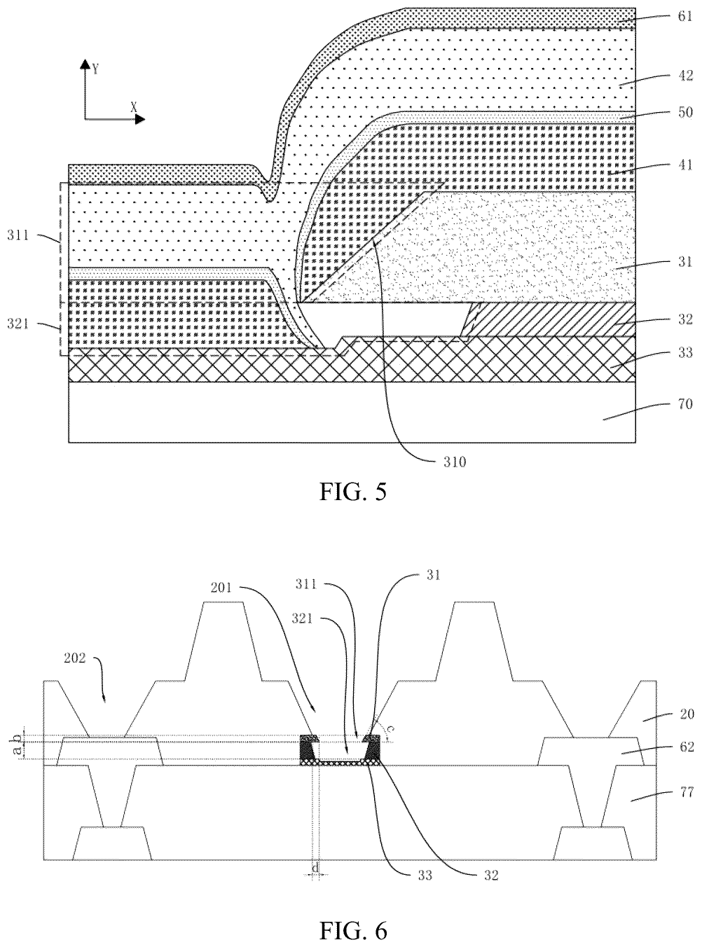

Referring to FIG. 4 and FIG. 5, one embodiment of the present application provides a display panel. The display panel includes a substrate 10, a first electrode layer 620, a pixel definition layer 20, an isolation structure 30, a first light-emitting layer 41, a charge generation layer 50, a second light-emitting layer 42, and a second electrode layer 61.

The first electrode layer 620 is located on the substrate 10 and includes a plurality of first electrodes 62 that are spaced apart.

The pixel definition layer 20 is disposed on one side of the first electrode layer 620 that is away from the substrate 10, and includes a plurality of pixel openings 202 arranged corresponding to the first electrodes 62, and a first opening 201 set between adjacent pixel openings 202.

The isolation structure 30 is placed between the substrate 10 and the pixel definition layer 20 and is arranged corresponding to the first opening 201. The isolation structure 30 consists of stacked layers: a first isolation layer 31 and a second isolation layer 32. The second isolation layer 32 is located between the substrate 10 and the first isolation layer 31. The first isolation layer 31 includes a first sub-opening 311 that is arranged corresponding to the first opening 201, and the second isolation layer 32 includes a second sub-opening 321 that is arranged corresponding to the first sub-opening 311. A minimum opening area of the second sub-opening 321 is larger than a minimum opening area of the first sub-opening 311, allowing the second sub-opening 321 to communicate with the first opening 201 through the first sub-opening 311.

The first light-emitting layer 41 is placed on one side of the pixel definition layer 20 that is away from the substrate 10 and is interrupted at the isolation structure 30.

The charge generation layer 50 is positioned on one side of the first light-emitting layer 41 that is away from the pixel definition layer 20 and is also interrupted at the isolation structure 30.

The second light-emitting layer 42 is placed on one side of the charge generation layer 50 that is away from the first light-emitting layer 41.

The second electrode layer 61 is located on one side of the second light-emitting layer 42 that is away from the substrate 10, and the second electrode layer 61 is continuous across the isolation structure 30.

Furthermore, an opening area of the first sub-opening 311 on one side away from the substrate 10 is greater than an opening area of the first sub-opening 311 on one side closer to the substrate 10.

In practice, this embodiment of the application designs the opening areas of the first sub-opening 311 in the first isolation layer 31 such that the opening area on the side away from the substrate 10 is larger than the opening area on the side closer to the substrate 10. This design isolates the charge generation layer 50. Further, the second light-emitting layer 42 is positioned on the side of the charge generation layer 50 that is away from the first light-emitting layer 41, and the second electrode layer 61 continuously covers the side of the second light-emitting layer 42 that is away from the substrate 10. This arrangement not only addresses the issue of unintended activation of adjacent pixels but also reduces the likelihood of a short circuit occurring between the charge generation layer 50 and the second electrode layer 61, thereby improving the production yield and display performance of the display panel.

In one embodiment of the present application, the second light-emitting layer is continuously arranged at the isolation structure.

In one embodiment of the present application, an angle between an inner wall of the first sub-opening and a first direction is less than 90 degrees. The first direction is towards the inner wall of the first sub-opening from a center of the first sub-opening, and the first direction is parallel to the substrate.

In one embodiment of the present application, the inner wall of the first sub-opening includes multiple sub-faces. An angle between the sub-face that is further from the center of the first sub-opening and the first direction is less than an angle between the sub-face closer to the center of the first sub-opening and the first direction.

In one embodiment of the present application, the sub-faces of the first sub-opening include a first sub-face which is close to the center of the first sub-opening, and a second sub-face which is further from the center of the first sub-opening. The first sub-face is connected to the second sub-face.

Furthermore, the first light-emitting layer includes a first recess located on one side of the first sub-face close to the center of the first sub-opening, and a second recess located at a junction between the first sub-face and the second sub-face.

In one embodiment of the present application, the charge generation layer includes a first sub-part located within the first sub-opening, a second sub-part located on one side of the inner wall of the first sub-opening that is away from the substrate, and a third sub-part located further from the center of the first sub-opening than the second sub-part.

The first sub-part and the second sub-part are spaced apart at the location of the first recess.

The second sub-part is either connected to the third sub-part or spaced apart from the third sub-part at the location of the second recess.

In one embodiment of the present application, the second light-emitting layer includes a third recess and a fourth recess. The third recess is aligned with the first recess along a second direction, and the fourth recess is aligned with the second recess along the second direction. The second direction is from the substrate towards the pixel definition layer.

In one embodiment of the present application, the second electrode layer continuously covers both the third recess and the fourth recess.

In one embodiment of the present application, the angle between the inner wall of the first sub-opening and the first direction is greater than or equal to 10 degrees and less than or equal to 70 degrees.

In one embodiment of the present application, a total thicknesses of the first isolation layer and the second isolation layer is greater than or equal to a total thickness of the first light-emitting layer and the charge generation layer, but less than or equal to a total thickness of the first light-emitting layer, the charge generation layer, and the second light-emitting layer.

In one embodiment of the present application, the isolation structure further includes a third isolation layer. The third isolation layer is disposed between the second isolation layer and the substrate and is stacked with the second isolation layer.

Specifically, referring to FIGS. 1 and 2, the display panel includes a substrate 10, a driving circuit layer 70 disposed on the substrate 10, a pixel definition layer 20 located on one side of the driving circuit layer 70 that is away from the substrate 10, and a light-emitting device layer placed on one side of the pixel definition layer 20 that is away from the driving circuit layer 70.

In one embodiment, the display panel also includes a light extraction layer and an encapsulation layer, both disposed on one side of the light-emitting device layer that is away from the pixel definition layer 20. The light extraction layer and the encapsulation layer are not shown in the drawings.

In one embodiment, the driving circuit layer 70 includes: a buffer layer 71 disposed on the substrate 10, a first insulation layer 72 disposed on the buffer layer 71, a second insulation layer 73 disposed on the first insulation layer 72, a first gate insulation layer 74 disposed on the second insulation layer 73, a second gate insulation layer 75 disposed on the first gate insulation layer 74, a first organic planarization layer 76 on the second gate insulation layer 75, and a second organic planarization layer 77 disposed on the first organic planarization layer 76. Additionally, the driving circuit layer 70 further includes a thin-film transistor 78 disposed on the substrate 10. This thin-film transistor 78 includes an active layer set on the first insulation layer 72 and covered by the second insulation layer 73, a first gate placed on the second insulation layer 73 and covered by the first gate insulation layer 74, a second gate disposed on the first gate insulation layer 74 and covered by the second gate insulation layer 75, and a source and a drain located on the second gate insulation layer 75 and covered by the first organic planarization layer 76. Furthermore, the driving circuit layer 70 includes a light-shielding layer positioned between the active layer and the substrate 10, and a signal line connected to the light-shielding layer to provide a stable voltage to the light-shielding layer. The light-shielding layer is disposed on the buffer layer 71 and covered by the first insulation layer 72. The signal line is placed on the second gate insulation layer 75. The signal line passes through the second gate insulation layer 75, the first gate insulation layer 74, the second insulation layer 73, and the first insulation layer 72 to overlap with the light-shielding layer. Further, the driving circuit layer 70 includes an interconnect line set on the first organic planarization layer 76 and overlapping with the drain. This interconnect line is used to connect the drain to the light-emitting device layer, facilitating the transmission of signals.

The light-emitting device layer includes a first electrode layer 620 disposed on the second organic planarization layer 77. The first electrode layer 620 includes a plurality of first electrodes 62. The pixel definition layer 20 is located on the second organic planarization layer 77 and includes a plurality of pixel openings 202. Each pixel opening 202 is disposed corresponding to one of the first electrodes 62. The first electrode 62 can be connected to the drain.

In the present application, the light-emitting device layer is a Tandem light-emitting device, meaning that the light-emitting device layer includes multiple light-emitting layers. This configuration can effectively enhance the light-emitting efficiency and lifespan of the light-emitting device layer.

In one embodiment, the light-emitting device layer further includes a first light-emitting layer 41 disposed on the pixel definition layer 20, a charge generation layer 50 disposed on one side of the first light-emitting layer 41 that is away from the pixel definition layer 20, a second light-emitting layer 42 located on one side of the charge generation layer 50 that is away from the first light-emitting layer 41, and a second electrode layer 61 placed on one side of the second light-emitting layer 42 that is away from the charge generation layer 50.

It should be noted that the first light-emitting layer 41 can include a sequence of layers stacked in a direction from the first electrode 62 towards the second electrode layer 61, consisting of a hole injection layer, a hole transport layer, and a first organic light-emitting layer. Similarly, the second light-emitting layer 42 can include a stack of a second organic light-emitting layer, an electron transport layer, and an electron injection layer; all arranged in sequence from the first electrode 62 towards the second electrode layer 61. The first organic light-emitting layer and the second organic light-emitting layer are arranged corresponding to the pixel openings 202, whereas the hole injection layer, the hole transport layer, the electron transport layer, and the electron injection layer can cover the side of the pixel definition layer 20 that is away from the driving circuit layer 70.

Furthermore, the pixel definition layer 20 features a first opening 201, and the first opening 201 is located between adjacent pixel openings 202.

In the present embodiment, the display panel further includes an isolation structure 30 set on one side of the driving circuit layer 70 that is away from the substrate 10. The isolation structure 30 can be set in the same layer as the first electrode 62, meaning that the isolation structure 30 is positioned on a surface of the second organic planarization layer 77 that is away from the first organic planarization layer 76. The isolation structure 30 is disposed corresponding to the first opening 201.

The isolation structure 30 includes a stacked arrangement of a first isolation layer 31 and a second isolation layer 32, with the second isolation layer 32 positioned between the substrate 10 and the first isolation layer 31. The first isolation layer 31 includes a first sub-opening 311 located corresponding to the first opening 201. The second isolation layer 32 includes a second sub-opening 321 located corresponding to the first opening 201. A minimum opening area of the second sub-opening 321 is larger than a minimum opening area of the first sub-opening 311, and the second sub-opening 321 is connected to the first opening 201 through the first sub-opening 311. This means that an inner wall of the first sub-opening 311 protrudes beyond an inner wall of the second sub-opening 321, forming a bottom-cut structure at the locations of the first sub-opening 311 and the second sub-opening 321. Essentially, the bottom-cut structure surrounds both the first sub-opening 311 and the second sub-opening 321 within the isolation structure 30.

Moreover, an opening area of the first sub-opening 311 on one side away from the substrate 10 is larger than an opening area on one side closer to the substrate 10. Furthermore, an angle between the inner wall 310 of the first sub-opening 311 and the first direction X is less than 90 degrees. The first direction X is defined as a direction from a center of the first sub-opening 311 towards the inner wall 310 of the first sub-opening 311, and the first direction X is parallel to the substrate 10. In one embodiment, the inner wall 310 of the first sub-opening 311 has a shape of an upright trapezoidal side.

Both the first light-emitting layer 41 and the charge generation layer 50 are interrupted/separated at the isolation structure 30, while the second light-emitting layer 42 and the second electrode layer 61 are continuous over the isolation structure 30. By designing the inner wall 310 of the first isolation layer 31 such that the opening area of the first sub-opening 311 on the side away from the substrate 10 is larger than that on the side closer to the substrate 10, and thus ensuring the angle between the inner wall 310 of the first sub-opening 311 and the first direction X is less than 90 degrees, it is possible to interrupt the charge generation layer 50. This configuration also allows the second light-emitting layer 42 and the second electrode layer 61 to continuously cover the side of the charge generation layer 50 that is away from the substrate 10. Consequently, this approach not only addresses the issue of unintentionally lighting adjacent pixels but also reduces the probability of short circuits between the charge generation layer 50 and the second electrode layer 61, thereby enhancing the production yield and display performance of the display panel.

It should be noted that in the present embodiment, the charge generation layer 50 includes at least an n-type charge generation layer. The n-type charge generation layer is formed by doping electron transport materials with an n-type dopant (n dopant), which results in a higher electron mobility. Consequently, in this embodiment, the n-type charge generation layer is interrupted to address the issue of unintentionally lighting adjacent pixels in the display panel.

In one embodiment, the charge generation layer 50 includes an n-type charge generation layer, and the second light-emitting layer 42 includes a p-type charge generation layer situated between the n-type charge generation layer and the second organic light-emitting layer. In this case, the interruption of the n-type charge generation layer is implemented.

In another embodiment, the charge generation layer 50 includes both n-type and p-type charge generation layers. In that case, both the n-type and p-type charge generation layers are interrupted.

Referring to FIGS. 4, 5, and 6, in one embodiment, an angle c between the inner wall 310 of the first sub-opening 311 and the first direction X is greater than or equal to 10 degrees and less than or equal to 70 degrees. More preferably, the angle c between the inner wall 310 of the first sub-opening 311 and the first direction X is greater than or equal to 50 degrees and less than or equal to 60 degrees.

Furthermore, a sum of a thickness a of the first isolation layer 31 and a thickness b of the second isolation layer 32 is greater than or equal to a sum of the thicknesses of the first light-emitting layer 41 and the charge generation layer 50, yet less than or equal to a sum of the thicknesses of the first light-emitting layer 41, the charge generation layer 50, and the second light-emitting layer 42. This configuration effectively isolates the first light-emitting layer 41 and the charge generation layer 50, while avoiding the interruption of the second light-emitting layer 42 and the second electrode layer 61. Such configuration ensures that while improving the issue of unwanted light emission from adjacent pixels, it also reduces the probability of short circuits occurring between the charge generation layer 50 and the second electrode layer 61.

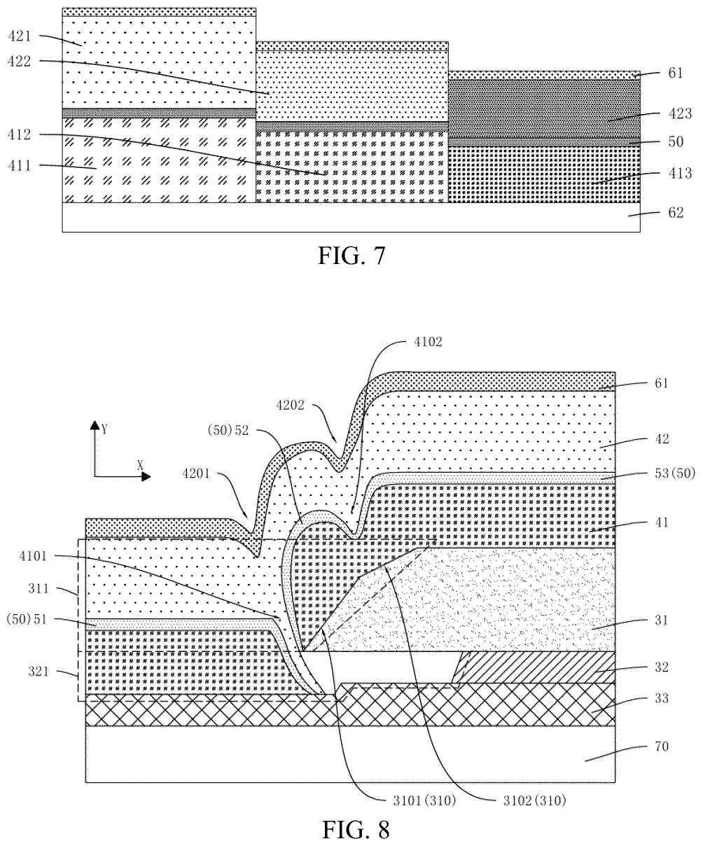

Referring to FIGS. 4, 5, and 7, in one embodiment, the light-emitting device layer includes a first pixel, a second pixel, and a third pixel. The first light-emitting layer 41 includes a first light-emitting sub-layer 411 corresponding to the first pixel, a second light-emitting sub-layer 412 corresponding to the second pixel, and a third light-emitting sub-layer 413 corresponding to the third pixel. Similarly, the second light-emitting layer 42 includes a fourth light-emitting sub-layer 421 corresponding to the first pixel, a fifth light-emitting sub-layer 422 corresponding to the second pixel, and a sixth light-emitting sub-layer 423 corresponding to the third pixel. A thickness of the first light-emitting sub-layer 411 is greater than a thickness of the second light-emitting sub-layer 412, and the thickness of the second light-emitting sub-layer 412 is greater than a thickness of the third light-emitting sub-layer 413. Similarly, a thickness of the fourth light-emitting sub-layer 421 is greater than a thickness of the fifth light-emitting sub-layer 422, and the thickness of the fifth light-emitting sub-layer 422 is greater than a thickness of the sixth light-emitting sub-layer 423. In this embodiment, to ensure that the charge generation layer 50 corresponding to the first, second, and third pixels is interrupted, the sum of the thicknesses a and b of the first isolation layer 31 and the second isolation layer 32 need to be greater than or equal to the sum of the thicknesses of the first light-emitting sub-layer 411 corresponding to the first pixel and the charge generation layer 50. Additionally, to avoid interrupting the second light-emitting layer 42 corresponding to the first, second, and third pixels, the combined thicknesses of the first and second isolation layers need to be less than or equal to the sum of the thicknesses of the third light-emitting sub-layer 413 corresponding to the third pixel, the charge generation layer 50, and the sixth light-emitting sub-layer 423.

In one embodiment, the first pixel is a red pixel, the second pixel is a green pixel, and the third pixel is a blue pixel.

In one embodiment, the thickness b of the first isolation layer 31 is greater than or equal to 0.01 micrometers and less than or equal to 0.2 micrometers. A distance d from the inner wall 310 of the first sub-opening 311 near the center of the first sub-opening 311 along the first direction X to the sidewall of the first opening 201 is greater than or equal to 0.1 micrometers.

In one embodiment, the isolation structure 30 also includes a third isolation layer 33. The third isolation layer 33 is disposed between the second isolation layer 32 and the substrate 10 and is stacked with the second isolation layer 32. The third isolation layer 33 is located at a bottom of the second sub-opening 321, which does not penetrate through the third isolation layer 33. In one embodiment, the second sub-opening 321 can partially penetrate through the third isolation layer 33. As etching is required to form the second opening 301 and the undercut structure in the isolation structure 30, this embodiment includes adding the third isolation layer 33 between the second isolation layer 32 and the driving circuit layer 70. The third isolation layer 33 acts as an etch stop layer to prevent damage to the driving circuit layer 70 during the etching process.

In one embodiment, a material of the first isolation layer 31 is the same as a material of the third isolation layer 33, while differing from a material of the second isolation layer 32. This configuration utilizes the etch selectivity between materials to achieve the undercut structure. For example, the material for both the first isolation layer 31 and the third isolation layer 33 can include silicon oxide, whereas the material for the second isolation layer 32 can include silicon nitride.

In one embodiment of this application, please refer to FIGS. 4 and 5, where the inner wall 310 of the first sub-opening 311 is a flat surface. In this embodiment, the first light-emitting layer 41 is interrupted on the side of the inner wall 310 that is closer to the center of the first sub-opening 311, forming a recess; consequently, the charge generation layer 50 is also interrupted at this recess, specifically on the same side of the inner wall 310 near the center of the first sub-opening 311.

Furthermore, both the second light-emitting layer 42 and the second electrode layer 61 continuously cover the side of the inner wall 310 of the first sub-opening 311 that is near the center of the first sub-opening 311, as well as the inner wall 310 of the first sub-opening 311. The second light-emitting layer 42 is disposed between the second electrode layer 61 and the charge generation layer 50, which effectively prevents a short circuit between the second electrode layer 61 and the charge generation layer 50.

In another embodiment of the present application, please refer to FIGS. 4 and 8, where the inner wall 310 of the first sub-opening 311 includes multiple sub-faces. An angle between the sub-face on one side farther from the center of the first sub-opening 311 and the first direction X is smaller than an angle between the sub-face closer to the center of the first sub-opening 311 and the first direction X. This means that the inner wall 310 of the first sub-opening 311 forms multiple sub-faces with varying slope angles, and the slope angles of these sub-faces increase in the direction toward the center of the first sub-opening 311.

Specifically, the sub-faces include a first sub-face 3101, which is closer to the center of the first sub-opening 311, and a second sub-face 3102, which is farther from the center of the first sub-opening 311. The first sub-face 3101 is connected to the second sub-face 3102.

In this arrangement, the first light-emitting layer 41 includes a first recess 4101 positioned on one side of the first sub-face 3101 near the center of the first sub-opening 311, and a second recess 4102 located at a junction where the first sub-face 3101 and the second sub-face 3102 connect. The first light-emitting layer 41 is interrupted at the first recess 4101, but is continuously arranged at the second recess 4102.

The charge generation layer 50 includes a first sub-part 51 located within the first sub-opening 311, a second sub-part 52 located on the inner wall 310 of the first sub-opening 311 on the side away from the substrate 10, and a third sub-part 53 located near the side of the second sub-part 52 that is away from the center of the first sub-opening 311. In this arrangement, the first sub-part 51 and the second sub-part 52 are spaced apart at the location of the first recess 4101, while the second sub-part 52 is connected to the third sub-part 53.

It is understandable that in the present embodiment, the explanation uses an example where there are two sub-faces. However, the number of sub-faces can be greater, such as three, four, or five.

The second light-emitting layer 42 includes a third recess 4201 and a fourth recess 4202. The third recess 4201 is aligned with the first recess 4101 along the second direction Y, and the fourth recess 4202 is aligned with the second recess 4102 along the same second direction Y The second direction Y is a direction from the substrate 10 towards the pixel definition layer 20. Furthermore, the second electrode layer 61 continuously covers both the third recess 4201 and the fourth recess 4202.

Further, in the present embodiment, the design of the inner wall 310 of the first sub-opening 311 includes multiple sub-faces with varying slope angles. This design enables the first light-emitting layer 41 and the second light-emitting layer 42 to form concave and convex surfaces above the inner wall 310 of the first sub-opening 311. The concave and convex features increase a path length of the second electrode layer 61 along the inner wall 310 of the first sub-opening 311, thereby increasing the electrical resistance of the second electrode layer 61 at this location. Such an increase in resistance helps to reduce the likelihood of a short circuit occurring between the second electrode layer 61 and the charge generation layer 50.

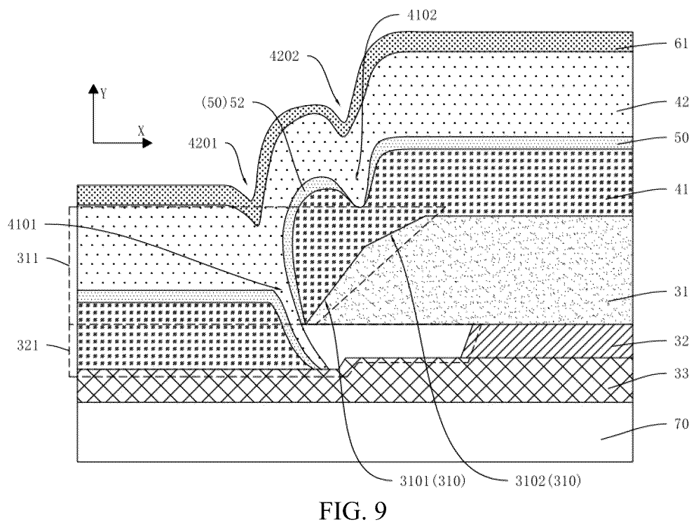

In another embodiment of the present application, as illustrated by combining FIGS. 4 and 9, this embodiment differs from the embodiment shown in FIG. 8 in that the second sub-part 52 and the third sub-part 53 are spaced apart at the second recess 4102. This means that in addition to the charge generation layer 50 being interrupted at the inner wall 310 of the first sub-opening 311 at one end near the center of the first sub-opening 311, the charge generation layer 50 can also be interrupted again above the inner wall 310 of the first sub-opening 311. The number of such interruptions can vary depending on the number of sub-faces and is not limited in this disclosure.

Moreover, the design of the inner wall 310 of the first sub-opening 311 in this embodiment involves creating multiple sub-faces with different slope angles. This design allows the first light-emitting layer 41 and the second light-emitting layer 42 to form a contoured film with concave and convex features above the inner wall 310 of the first sub-opening 311. Consequently, this design increases the path length of the second electrode layer 61 along the inner wall 310 of the first sub-opening 311, which increases the electrical resistance of the second electrode layer 61 at the inner wall 310 of the first sub-opening 311, thus reducing the likelihood of a short circuit occurring between the second electrode layer 61 and the charge generation layer 50. Additionally, in the present embodiment, the charge generation layer 50 can be further interrupted above the inner wall 310 of the first sub-opening 311, thereby further reducing the probability of a short circuit between the second electrode layer 61 and the charge generation layer 50, and enhancing the light output efficiency and display quality of the display panel.

Additionally, the present application further provides a display device that includes the display panel described in the above embodiments.

It is understandable that since the display device includes the display panel from the above embodiments, the display device possesses the same beneficial effects as described in the embodiments of the display panel, which will not be reiterated here.

In the descriptions of the various embodiments provided above, each is emphasized differently. For details not elaborated in one embodiment, reference can be made to the descriptions relevant to other embodiments.

The above is a detailed introduction to a display panel and a display device provided by the embodiments of the present application. Specific examples are used in this disclosure to illustrate the principles and implementation methods of the present application. These examples are intended solely to aid in understanding the technical solutions and core ideas of this application. It should be understood by those skilled in the art that modifications can still be made to the technical solutions described in the aforementioned embodiments, or that some technical features can be equivalently replaced. These modifications or replacements do not deviate from the essence of the technical solutions of the embodiments of this application.

What is claimed is:

1. A display panel, comprising:
a substrate;
a first electrode layer, disposed on one side of the substrate, and comprising a plurality of first electrodes that are spaced apart;
a pixel definition layer, disposed on one side of the first electrode layer away from the substrate, wherein the pixel definition layer comprises a plurality of pixel openings corresponding to the first electrodes and a first opening located between adjacent pixel openings;
an isolation structure, disposed between the substrate and the pixel definition layer, and arranged corresponding to the first opening, wherein isolation structure comprises a first isolation layer and a second isolation layer stacked on each other, the second isolation layer is located between the substrate and the first isolation layer, the first isolation layer comprises a first sub-opening corresponding to the first opening, the second isolation layer comprises a second sub-opening corresponding to the first sub-opening, a minimum opening area of the second sub-opening is greater than a minimum opening area of the first sub-opening, and the second sub-opening communicates with the first opening through the first sub-opening;
a first light-emitting layer, disposed on one side of the pixel definition layer away from the substrate and interrupted at the isolation structure;
a charge generation layer, disposed on one side of the first light-emitting layer away from the pixel definition layer, and interrupted at the isolation structure;
a second light-emitting layer, disposed on one side of the charge generation layer away from the first light-emitting layer; and
a second electrode layer, disposed on one side of the second light-emitting layer away from the substrate, and continuously arranged at the isolation structure,
wherein an opening area of the first sub-opening on one side away from the substrate is greater than an opening area on one side near the substrate.

2. The display panel according to claim 1, wherein the second light-emitting layer is continuously arranged at the isolation structure.

3. The display panel according to claim 1, wherein an angle between an inner wall of the first sub-opening and a first direction is less than 90 degrees, the first direction is from a center of the first sub-opening towards the inner wall of the first sub-opening, and the first direction is parallel to the substrate.

4. The display panel according to claim 3, wherein the inner wall of the first sub-opening comprises multiple sub-faces, and an angle between the sub-face farther from the center of the first sub-opening and the first direction is smaller than an angle between the sub-face closer to the center of the first sub-opening and the first direction.

5. The display panel according to claim 3, wherein the sub-faces comprise a first sub-face that is close to the center of the first sub-opening and a second sub-face that is away from the center of the first sub-opening, with the first sub-face connecting to the second sub-face; and
the first light-emitting layer comprises a first recess located at one side of the first sub-face near the center of the first sub-opening, and a second recess located at a junction where the first sub-face and the second sub-face connect.

6. The display panel according to claim 5, wherein the charge generation layer comprises a first sub-part located within the first sub-opening, a second sub-part located on one side of the inner wall of the first sub-opening away from the substrate, and a third sub-part located on one side of the second sub-part that is away from the center of the first sub-opening;
the first sub-part and the second sub-part are spaced apart at the first recess; and
the second sub-part and the third sub-part are connected, or the second sub-part and the third sub-part are spaced apart at the second recess.

7. The display panel according to claim 5, wherein the second light-emitting layer comprises a third recess and a fourth recess, the third recess is aligned with the first recess along a second direction, the fourth recess is aligned with the second recess along the second direction, and the second direction is from the substrate towards the pixel definition layer.

8. The display panel according to claim 7, wherein the second electrode layer continuously covers both the third recess and the fourth recess.

9. The display panel according to claim 3, wherein the angle between the inner wall of the first sub-opening and the first direction is greater than or equal to 10 degrees and less than or equal to 70 degrees.

10. The display panel according to claim 1, wherein a total thickness of the first isolation layer and the second isolation layer is greater than or equal to a total thickness of the first light-emitting layer and the charge generation layer, and less than or equal to a total thickness of the first light-emitting layer, the charge generation layer, and the second light-emitting layer.

11. The display panel according to claim 1, wherein the isolation structure further comprises a third isolation layer, and the third isolation layer is disposed between the second isolation layer and the substrate and is stacked with the second isolation layer.

12. A display device, comprising a display panel, wherein the display panel comprises:
a substrate;
a first electrode layer, disposed on one side of the substrate, and comprising a plurality of first electrodes that are spaced apart;
a pixel definition layer, disposed on one side of the first electrode layer away from the substrate, wherein the pixel definition layer comprises a plurality of pixel openings corresponding to the first electrodes and a first opening located between adjacent pixel openings;
an isolation structure, disposed between the substrate and the pixel definition layer, and arranged corresponding to the first opening, wherein isolation structure comprises a first isolation layer and a second isolation layer stacked on each other, the second isolation layer is located between the substrate and the first isolation layer, the first isolation layer comprises a first sub-opening corresponding to the first opening, the second isolation layer comprises a second sub-opening corresponding to the first sub-opening, a minimum opening area of the second sub-opening is greater than a minimum opening area of the first sub-opening, and the second sub-opening communicates with the first opening through the first sub-opening;
a first light-emitting layer, disposed on one side of the pixel definition layer away from the substrate and interrupted at the isolation structure;
a charge generation layer, disposed on one side of the first light-emitting layer away from the pixel definition layer, and interrupted at the isolation structure;
a second light-emitting layer, disposed on one side of the charge generation layer away from the first light-emitting layer; and
a second electrode layer, disposed on one side of the second light-emitting layer away from the substrate, and continuously arranged at the isolation structure,
wherein an opening area of the first sub-opening on one side away from the substrate is greater than an opening area on one side near the substrate.

13. The display device according to claim 12, wherein the second light-emitting layer is continuously arranged at the isolation structure.

14. The display device according to claim 12, wherein an angle between an inner wall of the first sub-opening and a first direction is less than 90 degrees, the first direction is from a center of the first sub-opening towards the inner wall of the first sub-opening, and the first direction is parallel to the substrate.

15. The display device according to claim 14, wherein the inner wall of the first sub-opening comprises multiple sub-faces, and an angle between the sub-face farther from the center of the first sub-opening and the first direction is smaller than an angle between the sub-face closer to the center of the first sub-opening and the first direction.

16. The display device according to claim 14, wherein the sub-faces comprise a first sub-face that is close to the center of the first sub-opening and a second sub-face that is away from the center of the first sub-opening, with the first sub-face connecting to the second sub-face; and
the first light-emitting layer comprises a first recess located at one side of the first sub-face near the center of the first sub-opening, and a second recess located at a junction where the first sub-face and the second sub-face connect.

17. The display device according to claim 16, wherein the charge generation layer comprises a first sub-part located within the first sub-opening, a second sub-part located on one side of the inner wall of the first sub-opening away from the substrate, and a third sub-part located on one side of the second sub-part that is away from the center of the first sub-opening;
the first sub-part and the second sub-part are spaced apart at the first recess; and
the second sub-part and the third sub-part are connected, or the second sub-part and the third sub-part are spaced apart at the second recess.

18. The display device according to claim 16, wherein the second light-emitting layer comprises a third recess and a fourth recess, the third recess is aligned with the first recess along a second direction, the fourth recess is aligned with the second recess along the second direction, and the second direction is from the substrate towards the pixel definition layer.

19. The display device according to claim 18, wherein the second electrode layer continuously covers both the third recess and the fourth recess.

20. The display device according to claim 14, wherein the angle between the inner wall of the first sub-opening and the first direction is greater than or equal to 10 degrees and less than or equal to 70 degrees.
